(19) United States
(12) Patent Application Publication
(10) Pub. No.: US 2005/0085085 A1
(43) Pub. Date: Apr. 21, 2005

(54) Composite patterning with trenches

(76) Inventor: Yan Borodovsky, Portland, OR (US)

Correspondence Address: FISH & RICHARDSON, PC, 12390 EL CAMINO REAL, SAN DIEGO, CA, 92130-2081, US

(21) Appl. No.: 10/688,337

(22) Filed: Oct. 17, 2003

(51) Int. Cl. H01L 21/302; H01L 21/461

(52) U.S. Cl. 438/706

(57) ABSTRACT

Systems and techniques for printing substrates. In one implementation, a method includes patterning a substrate with a substantially arbitrary arrangement of features by introducing irregularity into an array of repeating lines and spaces between the lines.

### BACKGROUND

This disclosure relates to the printing of substrates using lithographic techniques.

Various lithographic techniques can be used to print patterns such as those that define integrated circuits in microelectronic devices. For example, optical lithography, e-beam lithography, UV and EUV lithography, x-ray lithography and imprint printing techniques can all be used to form micron- and submicron-sized features.

### DESCRIPTION OF DRAWINGS

FIG. 1 is a top view of a wafer.

FIG. 2 is a sectional view of a portion of a layout piece on a wafer during processing.

FIG. 3 is a top view of a layout piece after exposure and development to form latent image of an array of repeating lines.

FIG. 4 is a sectional view of the layout piece of FIG. 3.

FIGS. 5 and 6 are sectional views along the same plane as FIG. 4 after additional processing.

FIG. 7 shows a top view of a layout piece after exposure to form a pattern.

FIG. 8 shows a sectional view of the layout piece of FIG. 7.

FIGS. 9 and 10 are sectional views along the same plane as FIG. 8 after additional processing.

FIG. 11 shows a top view of a layout piece after stripping.

FIG. 12 shows a sectional view of the layout piece of FIG. 11.

FIG. 13 is a sectional view of a layout piece that includes a negative photoresist layer.

FIG. 14 shows a top view of a layout piece after a second exposure.

FIG. 15 shows a sectional view of the layout piece of FIG. 14.

FIGS. 16 and 17 are sectional views along the same plane as FIG. 15 after additional processing.

FIG. 18 shows a top view of a layout piece after stripping.

FIG. 19 shows a sectional view of the layout piece of FIG. 18.

FIG. 20 shows a composite optical lithography system.

FIG. 21 shows an example patterning system in the composite optical lithography system of FIG. 20.

FIG. 22 shows a flowchart of a process for generating a layout of a mask.

FIG. 23 shows a design layout.

FIG. 24 shows an interference pattern array layout.

FIG. 25 shows a remainder layout showing the difference between the interference pattern array layout of FIG. 24 and the design layout of FIG. 23.

FIG. 26 shows the remainder layout of FIG. 25 after resizing.

Like reference symbols in the various drawings indicate like elements.

### DETAILED DESCRIPTION

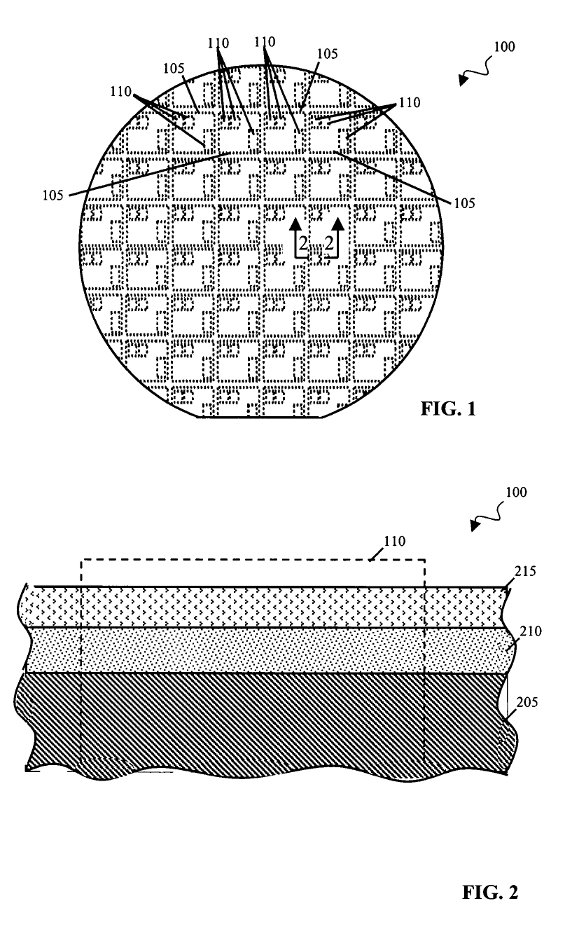

FIG. 1 shows a top view of a wafer 100. Wafer 100 is a semiconductor wafer being processed to form at least one integrated circuit device such as a microprocessor, a chipset device, or a memory device. For example, wafer 100 can be used to form a collection of SRAM memory devices. Wafer 100 can include silicon, gallium arsenide, or indium phosphide.

Wafer 100 includes an array of die portions 105. Wafer 100 can be diced or otherwise processed to separate die portions 105 and form a collection of dice that can be packaged to form individual integrated circuit devices. Each die portion 105 includes one or more layout pieces 110. A layout piece 110 is a section of a die portion 105 that includes a pattern. The pattern defined in a layout piece 110 generally contributes to the function of integrated circuit devices formed from die portions 105.

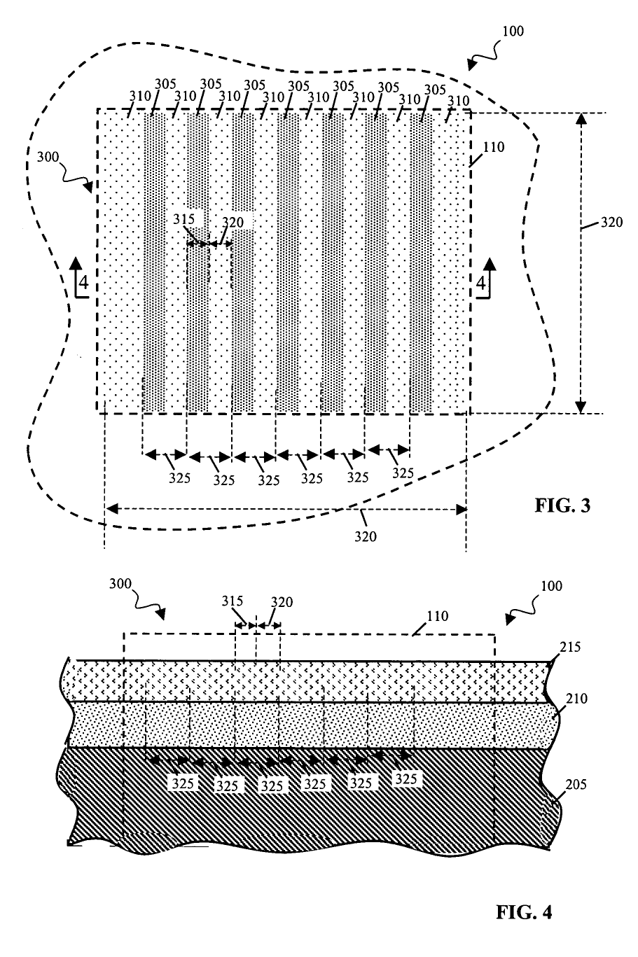

FIG. 2 is a sectional view of a portion of layout piece 110 on wafer 100. At the processing stage illustrated in FIG. 2, layout piece 110 includes a substrate 205, a pattern layer 210, and a resist layer 215. Substrate 205 can be the base wafer or another layer formed during previous processing. Pattern layer 210 is the portion of layout piece 110 that is to be patterned. Pattern layer 210 can be patterned to form all or a portion of a microelectronic device. Pattern layer 210 can be, e.g., an electrical insulator such as silicon dioxide or nitride, a semiconducting material such as p- or n-doped silicon, or a conducting layer such as copper or aluminum. Resist layer 215 is a material that is sensitive to one or more techniques for printing patterns. For example, resist layer 215 can be a positive or negative photoresist. The description of FIGS. 3-12 assumes resist layer 220 to be a positive photoresist.

Resist layer 215 can be exposed and developed to form a pattern. FIG. 3 is a top view and FIG. 4 is a sectional view of layout piece 110 after exposure to form a latent image 300. The top face of latent image 300 can be rectangular or square with a length 310 and a width 315 that occupies all or a portion of layout piece 110. Latent image 300 includes an alternating series of exposed lines 305 and unexposed spaces 310. Lines 305 can have a uniform width 315. Spaces 310 can have a uniform width 320. Widths 315, 320 can be equal or unequal. Lines 305 and spaces 310 in latent image 300 have a pitch 325. The pitch of features is the smallest spatial periodicity of the features. For example, pitch 325 of lines 305 is the sum of the width 315 of an exposed line 305 and the width 320 of an adjacent space 310. Pitch 325 can yield a k₁ factor smaller than or equal to 0.5. Factor k₁ is a term in the Rayleigh optical resolution expression and is given, in air, by the equation
k₁=(pitch/2)(NA/λ)
where:
   NA is the numerical aperture of the device that printed latent image 300, and
   λ is the wavelength of the electromagnetic radiation used to print latent image 300.
      For example, with a numerical aperture of an optical system approaching one, factor k₁ can approach 0.25.

Lines 305 can be exposed using any of a number of different lithographic techniques such as e-beam lithography, interference lithography, and optical lithography using phase-shifting masks and optical proximity correction techniques. For example, lines 305 can be exposed using interference lithography by exposing resist 215 using a pair of collimated interfering laser beams with a wavelength λ₁ to expose lines 305 with pitch 325 approaching ½λ₁. The orthogonal pair can be generated by splitting a single source using a beam splitter and interfering the reflections from two opposing mirrors, or the pair can be generated by using other interferometric techniques.

Lines 305 and spaces 310 can display features characteristic of the lithographic technique used to expose lines 305. For example, when lines 305 are exposed using interference lithography, lines 305 and spaces 310 can display the definition characteristic of interference lithography and a k₁ factor that approaches 0.25 with minimal feature distortion of the type that arises due to imperfections in projection printing systems and techniques. For example, lines 305 and spaces 310 can be formed without imperfections that arise due to the use of a mask, lenses, projection optics, and/or the backscattering of electrons. Lines 305 and spaces 310 can also show the influence of the relatively large depth of focus provided by interferometric lithography techniques. For example, the relatively large depth of focus of interferometric lithography techniques can provide precise control of the dimensional characteristics of features, especially relative to the control provided by optical systems in which high numerical apertures limit both the depth of field and the ability to print real world substrates that are not ideally flat.

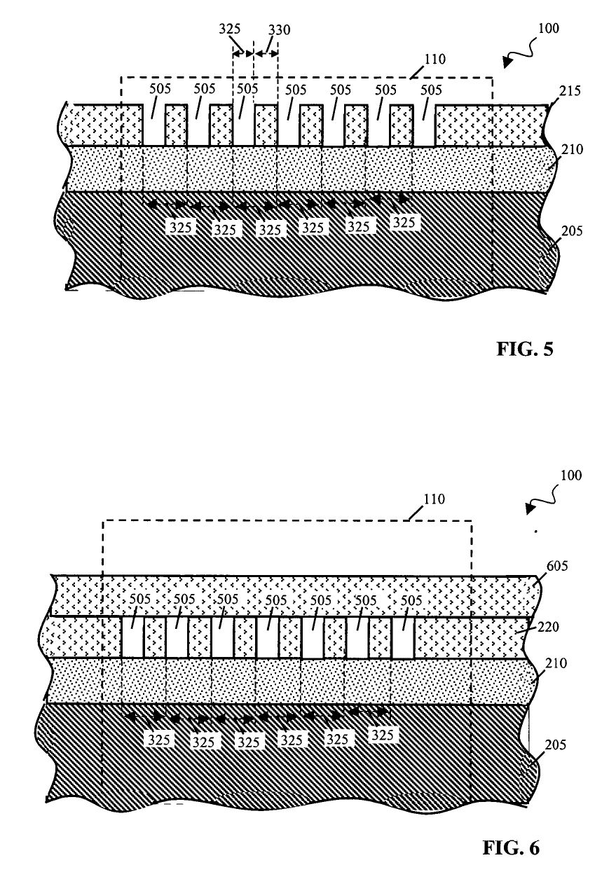

Lines 305 and spaces 310 can be used to define additional features in layout piece 110 on wafer 100. For example, as shown in FIG. 5, resist layer 215 can be developed to define a series of trenches 505. Resist layer 215 can be baked or cured as needed and, as shown in FIG. 6, a second resist layer 605 can be formed above resist layer 215. Resist layer 605 can either fill or cap trenches 505. Resist layer 605 can be formed, e.g., by spin coating photoresist on wafer 100.

Resist layer 605 can be formed directly on layer 215 or on an intervening protective layer (not shown). The protective layer can have a sufficiently high absorption coefficient to shield layer 205 from undesired, subsequent exposure. The protective layer can also serve to isolate layers 215, 605 by preventing them from contacting.

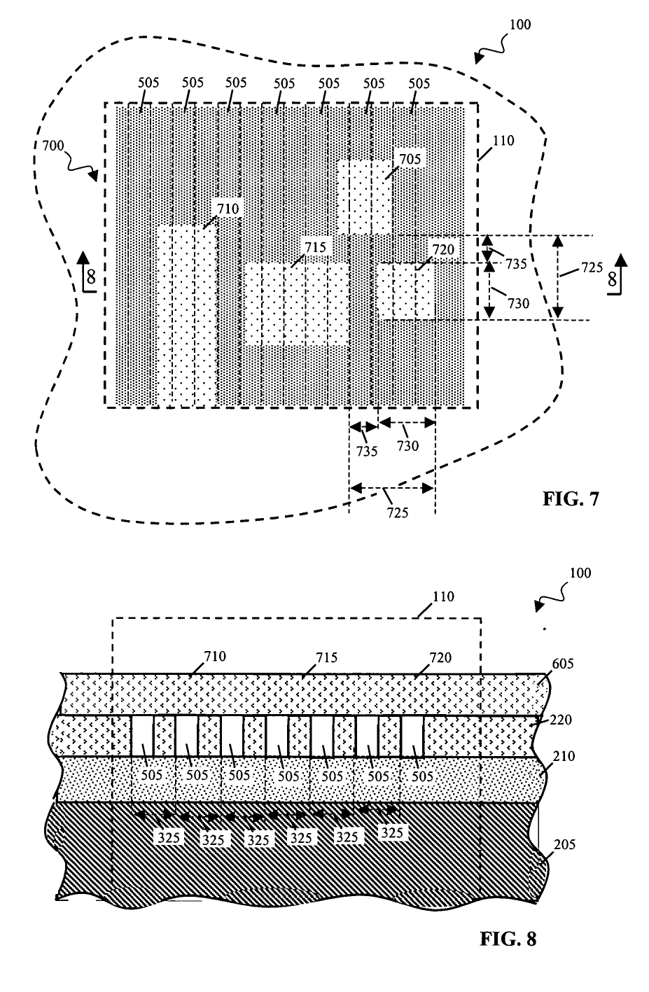

FIG. 7 shows a top view and FIG. 8 shows a sectional view of layout piece 110 after resist layer 605 has be exposed to form a latent image 700. Latent image 700 can include one or more unexposed regions 705, 710, 715, 720. Latent image 700 can be arbitrarily shaped in that unexposed regions 705, 710, 715, 720 need not include a repetitive order or arrangement. Unexposed regions 705, 710, 715, 720 can be dimensioned and positioned respective to trenches 505 to bridge one or more trenches 505. Unexposed regions 705, 710, 715, 720 can bridge one or more trenches 505 at arbitrary positions along trenches 505.

Unexposed regions 705, 710, 715, 720 in latent image 700 can be formed with a pitch 725. Region pitch 725 is the sum of the width 730 of region 720 and the shortest distance 735 to the next nearest regions 705, 710. For example, region element pitch 730 can be twice as large as line pitch 325. Region pitch 730 can thus yield a k₁ factor greater than or equal to 0.5. For example, factor k₁ can be greater than 0.7 with region pitch 725, assuming the same emission wavelength is used.

Since region pitch 725 yields a relatively large k₁ factor, latent image 700 can be formed using lithographic systems and techniques that have a lower resolution than the systems and techniques used to expose lines 305. For example, if lines 305 are formed using an interferometric lithography system with a k₁ factor approaching 0.25 and a wavelength λ₁, then latent image 700 can be formed using an optical lithography system with the same wavelength λ₁ and a k₁ factor above 0.5. For example, latent image 700 can be formed using a traditional binary optical lithography system or other lithographic systems such as optical projection lithography that are capable of achieving the lower resolution and acceptable overlay between lines 305 and spaces 310 and latent image 700.

The exposure or shielding of trenches 505 by latent image 700 can be used to introduce irregularity into the repeating array of trenches 505 after hardening of resist 605. In other words, the arbitrary shape of latent image 700 can be used to stop the periodic reoccurrence of features in layout piece 110. For example, the continuity of one or more trenches 505 can be ended at an arbitrary position along the trench 505.

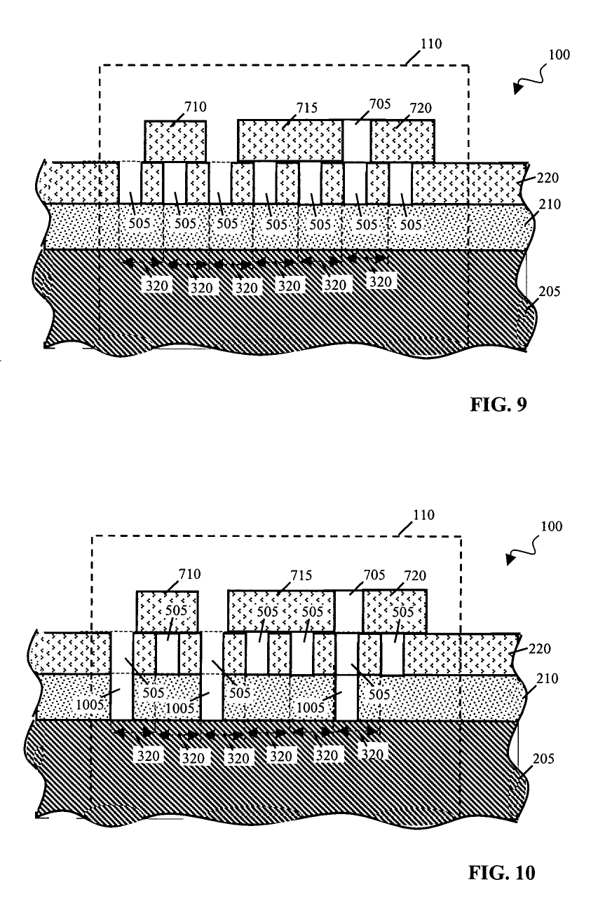

FIGS. 9 and 10 are sectional views along the same plane as FIG. 8 after additional processing. In particular, FIG. 9 shows layout piece 110 after resist layer 605 has been developed, leaving regions 705, 710, 715, 720 bridging selected trenches 505. Resist layer 605 can be baked as needed and, as shown in FIG. 10, an etch can be used to define trenches 1005 in pattern layer 210 of layout piece 110. For example, trenches 1005 can be defined using a dry plasma etch. Trenches 1005 can inherit the character of lines 305 that are characteristic of the lithographic technique used to expose lines 305. For example, when lines 305 are exposed using interference lithography, trenches 1005 can inherit the definition characteristic of interference lithography and a k₁ factor that approaches 0.25 with minimal feature distortion of the type that arises due to imperfections in projection printing systems and techniques.

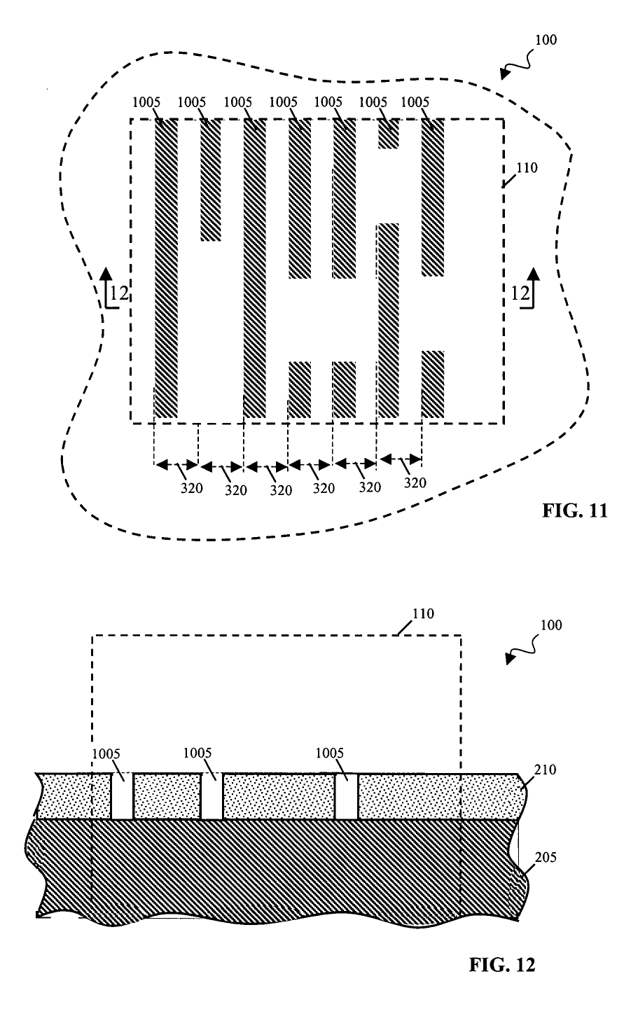

FIG. 11 shows a top view and FIG. 12 shows a sectional view of layout piece 110 after resist layers 220, 605 (including regions 705, 710, 715, 720) have been stripped. After removal of resist, pattern layer 210 in layout piece 110 includes an arbitrary arrangement of trenches 1005 with irregularity introduced into the repetition inherent in latent image 300. Trenches 1005 can have pitch 325 that is limited by the pitch available from the lithographic technique used to form latent image 300. After irregularity is introduced into latent image 300, the continuity of at least some of the small pitch latent lines 305 has been eliminated. This elimination of continuity can result in the formation of a layout pattern for use in making microelectronic devices.

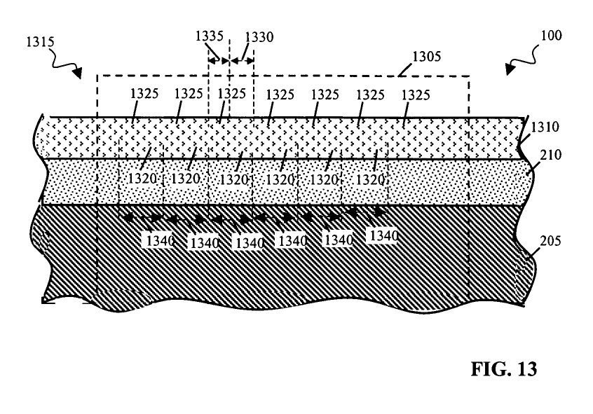

FIGS. 13-20 illustrate another technique for the composite patterning of lines. In particular, FIG. 13 shows a sectional view of a layout piece 1305 that includes a negative photoresist layer 1310. Negative resist layer 1310 has been exposed to form a latent image 1315. Latent image 1315 includes an alternating series of exposed lines 1320 and unexposed spaces 1325. Lines 1320 can have a uniform width 1330. Spaces 1325 can have a uniform width 1335. Widths 1330, 1335 can be equal or unequal. Lines 1320 in latent image 1300 have a pitch 1340. Line pitch 1340 can yield a k₁ factor smaller than 0.35. Factor k₁ can be smaller than 0.31. For example, factor k₁ can approach 0.25.

Lines 1320 can be exposed using any of a number of different lithographic techniques such as e-beam lithography, interference lithography, and optical lithography using phase-shifting masks and optical proximity correction techniques. For example, lines 1320 can be exposed using a pair of interfering, collimating laser beams with a wavelength λ₁ to expose lines 1320 with pitch 1340 equal to ½λ₁.

Lines 1320 and spaces 1325 can display features characteristic of the lithographic technique used to expose lines 1320. For example, when spaces 1325 are formed using interference lithography, spaces 1325 can have definition characteristic of interference lithography and a k₁ factor that approaches 0.25 with minimal feature distortion of the type that arises due to imperfections in projection printing systems and techniques. Spaces 1325 can also show the influence of the relatively large depth of focus provided by interferometric lithography techniques.

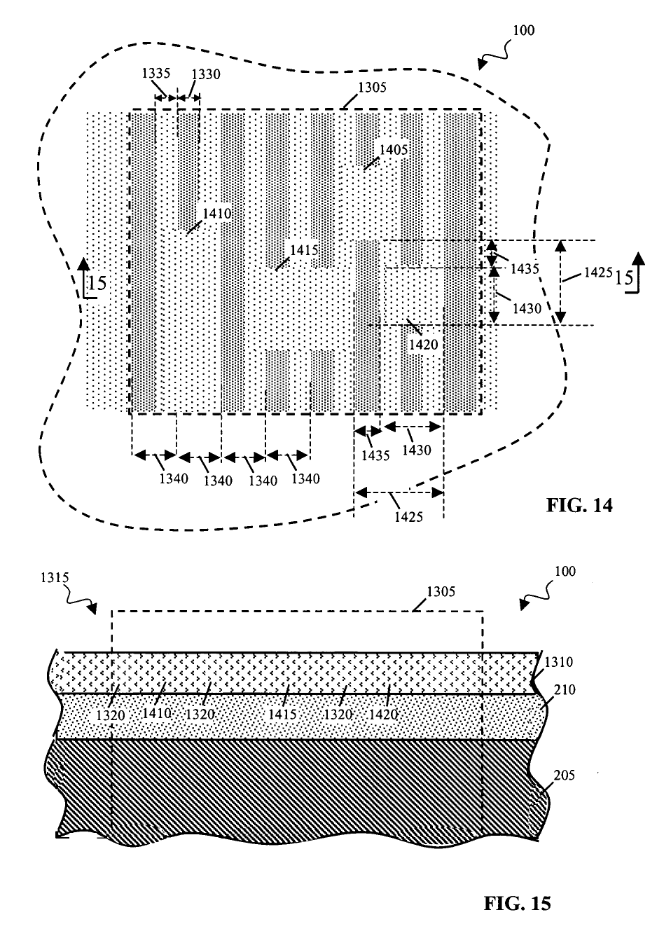

Unexposed spaces 1325 can be used to define additional features in layout piece 1305 on wafer 1310. FIG. 14 shows a top view and FIG. 15 shows a sectional view of layout piece 1305 after resist layer 1310 has be exposed a second time to expose regions 1405, 1410, 1415, 1420 of unexposed spaces 305. Exposed regions 1405, 1410, 1415, 1420 can be arbitrarily shaped and need not include a repetitive order or arrangement. Exposed regions 1405, 1410, 1415, 1420 can be dimensioned and positioned respective to exposed lines 1320 and regions of unexposed spaces 1325 to expose portions of spaces 1325 at arbitrary positions along spaces 1325. This exposure can cut the continuity of unexposed spaces 1325 and thereby introduce irregularity in the repeating array of latent lines 1320, 1325.

Exposed regions 1405, 1410, 1415, 1420 can be formed with a pitch 1425. Region pitch 1425 is the sum of the width 1430 of region 1420 and the shortest distance 1435 to the next nearest regions 1405, 1410. For example, region element pitch 1430 can be one and one half times as large as line pitch 1340. Region pitch 1430 can thus yield a k₁ factor greater than 0.4. For example, factor k₁ can be greater than 0.7 with region pitch 1430, assuming the same emission wavelength is used.

Since region pitch 1430 yields a relatively large k₁ factor, regions 1405, 1410, 1415, 1420 can be exposed using lithographic systems and techniques that have a lower resolution than the systems and techniques used to expose lines 1325. For example, if features 1325 are exposed using an interferometric lithography system with a k₁ factor approaching 0.25 and a wavelength λ₁, then regions 1405, 1410, 1415, 1420 can be exposed using an optical lithography system with the same wavelength λ₁, and a k₁ factor approaching 0.5. For example, regions 1405, 1410, 1415, 1420 can be exposed using a traditional binary optical lithography system, or other lithographic systems such as imprint and e-beam lithographic systems or direct write optical or e-beam capable of achieving the lower resolution and acceptable overlay between lines 305 and spaces 310 and regions 1405, 1410, 1415, 1420.

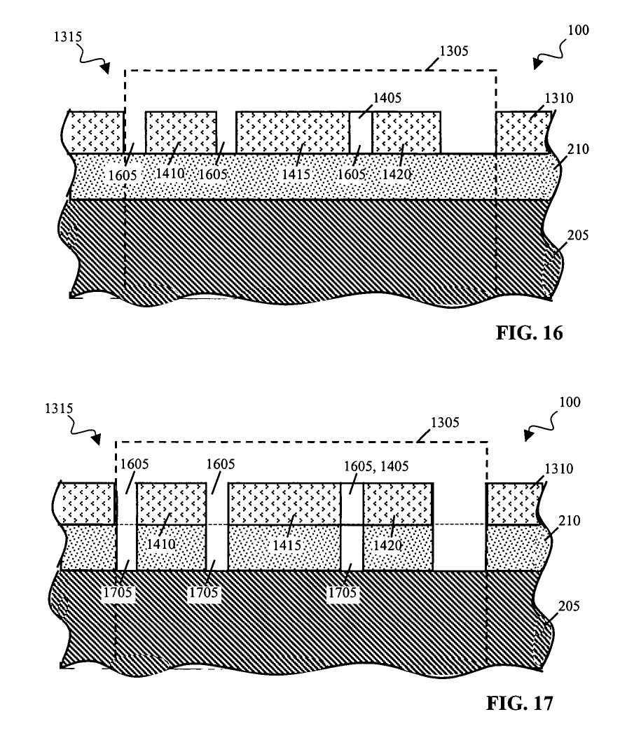

FIG. 16 shows a sectional view of layout piece 1305 after bake and development of resist layer 1310 define a series of trenches 1605. As shown in FIG. 17, an etch can be used to define trenches 1705 in pattern layer 210 of layout piece 110. For example, trenches 1705 can be defined using a dry plasma etch. Trenches 1705 can inherit the character of lines 1320 and spaces 1325 that are characteristic of the lithographic technique used to expose lines 1320. For example, when lines 1320 are exposed using interference lithography, trenches 1705 can inherit the definition characteristic of interference lithography and a k₁ factor that approaches 0.25 with minimal feature distortion of the type that arises due to imperfections in projection printing systems and techniques.

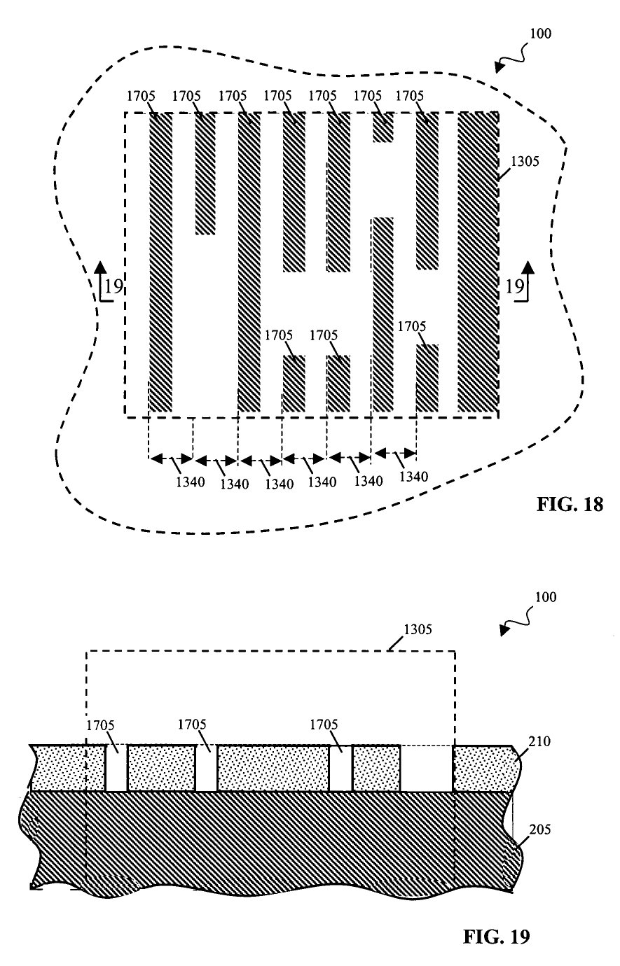

FIG. 18 shows a top view and FIG. 19 shows a sectional view of layout piece 110 after resist layer 1310 (including exposed regions 1405, 1410, 1415, 1420) has been stripped. After removal of resist 1310, pattern layer 210 in layout piece 110 includes an arbitrary arrangement of trenches 1705 with irregularity introduced into the repetition inherent in latent image 1315. Trenches 1705 can have pitch 1340 that is limited by the pitch available from the lithographic technique used to form latent image 1315. After irregularity is introduced into latent image 1315, the continuity of at least some of the small pitch latent spaces 1325 upon wafer 100 has been eliminated. As a result, a pattern layout that can be used in microelectronic devices can be formed.

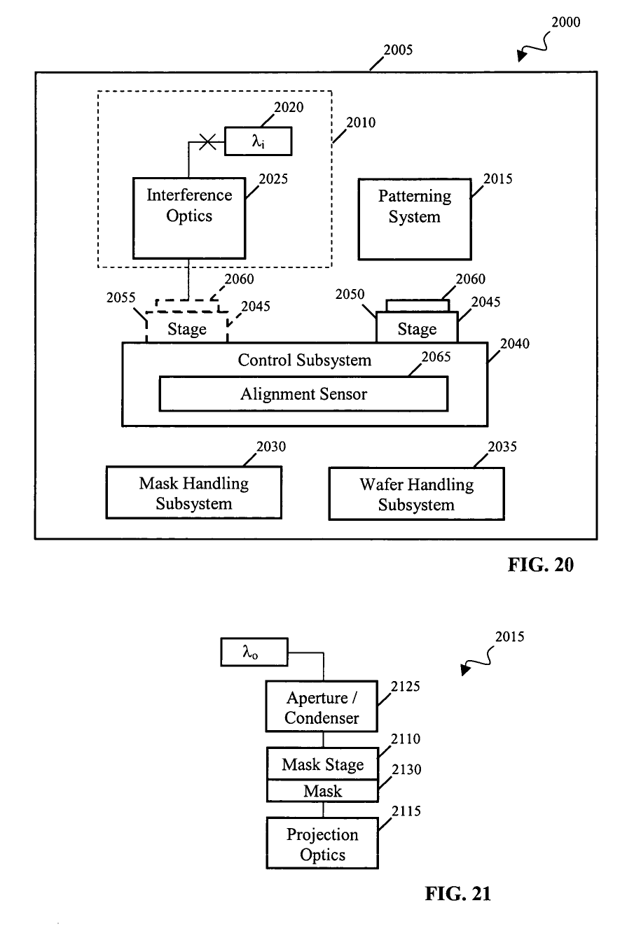

FIG. 20 shows a composite optical lithography system 2000. System 2000 includes an environmental enclosure 2005. Enclosure 2005 can be a clean room or other location suitable for printing features on substrates. Enclosure 1405 can also be a dedicated environmental system to be placed inside a clean room to provide both environmental stability and protection against airborne particles and other causes of printing defects.

Enclosure 2005 encloses an interference lithography system 2010 and a patterning system 2015. Interference lithography system 2010 includes a collimated electromagnetic radiation source 2020 and interference optics 2025 that together provide interferometric patterning of substrates. Patterning system 2015 can use any of a number of different approaches for patterning a substrate. For example, patterning system 2015 can be an e-beam projection system, an imprint printing system, or an optical projection lithography system. Patterning system 2015 can also be a maskless module, such as an electron beam direct write module, an ion beam direct write module, or an optical direct write module.

Systems 2010, 2015 can share a common mask handling subsystem 2030, a common wafer handling subsystem 2035, a common control subsystem 2040, and a common stage 2045. Mask handling subsystem 2030 is a device for positioning a mask in system 2000. Wafer handling subsystem 2035 is a device for positioning a wafer in system 2000. Control subsystem 2040 is a device for regulating one or more properties or devices of system 2000 over time. For example, control subsystem 2040 can regulate the position or operation of a device in system 2000 or the temperature or other environmental qualities within environmental enclosure 2005.

Control subsystem 2040 can also translate stage 2045 between a first position 2050 and a second position 2055. Stage 2045 includes a chuck 2060 for gripping a wafer. At first position 2050, stage 2045 and chuck 2060 can present a gripped wafer to patterning system 2015 for patterning. At second position 2055, stage 2045 and chuck 2060 can present a gripped wafer to interference lithography system 2010 for interferometric patterning.

To ensure the proper positioning of a wafer by chuck 2060 and stage 2045, control subsystem 2040 includes an alignment sensor 2065. Alignment sensor 2065 can transduce and control the position of the wafer (e.g., using wafer alignment marks) to align a pattern formed using interference lithography system 2010 with a pattern formed by patterning system 2015. Such positioning can be used when introducing irregularity into a repeating array of interferometric features, as discussed above.

FIG. 21 shows an example optical lithographic implementation of patterning system 2015. In particular, patterning system 2015 can be a step-and-repeat projection system. Such a patterning system 2015 can include an illuminator 2105, a mask stage 2100, and projection optics 2105. Illuminator 2105 can include an electromagnetic radiation source 2120 and an aperture/condenser 2125. Source 2120 can be the same as source 2020 or source 2120 can be an entirely different device. Source 2120 can emit at the same or at a different wavelength as source 2020. Aperture/condenser 2125 can include one or more devices for collecting, collimating, filtering, and focusing the electromagnetic emission from source 2020 to increase the uniformity of illumination upon mask stage 2100. Patterning system 2015 can also include pupil filling shaping optics to shape illumination in a pupil of the projection system, as desired (not shown).

Mask stage 2100 can support a mask 2130 in the illumination path. Projection optics 2105 can be a device for reducing image size. Projection optics 2105 can include a filtering projection lens. As stage 2045 repeatedly translates a gripped wafer for exposure by illuminator 2105 through mask stage 2100 and projection optics 2105, alignment sensor 2065 can ensure that the exposures are aligned with a repeating array of interferometric features to introduce irregularity into the repeating array.

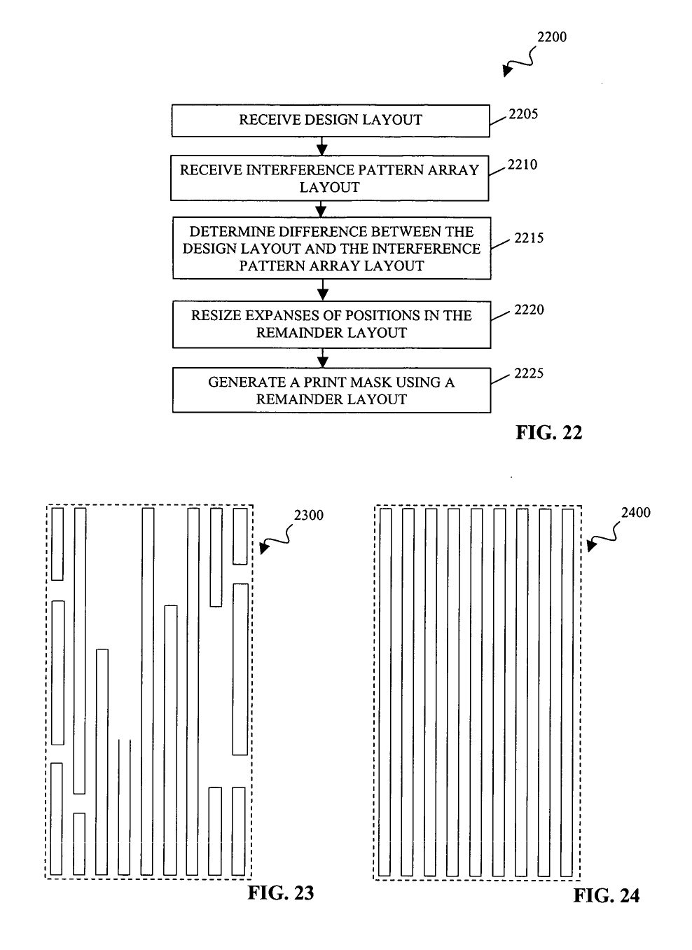

FIG. 22 shows a process 2200 for generating a layout of a mask that can be used in composite patterning. Process 2200 can be performed by one or more actors (such as a device manufacturer, a mask manufacturer, or a foundry), acting alone or in concert. Process 2200 can also be performed in whole or in part by a data processing device executing a set of machine-readable instructions.

The actor performing process 2200 receives a design layout at 2205. A design layout is the intended physical design of the substrate after processing. The design layout can be received in machine-readable form. The received design layout can include the intended physical design of a layout piece. The physical design of the layout piece can include a collection of trenches and lands between the trenches. The trenches and lands can be linear and parallel. The trenches and lands need not repeat regularly across the entire layout piece. For example, the continuity of trenches can be cut at arbitrary positions in the layout piece. FIG. 23 shows an example of such a design layout 2300.

Returning to FIG. 22, the actor performing process 2200 can also receive an interference pattern array layout at 2210. An interference pattern array layout is the intended pattern to be formed on a substrate by interference of electromagnetic radiation. The interference pattern array layout can be received in machine-readable form. The interference pattern array layout can be intended to be formed using interferometric lithography techniques. For example, the interference pattern array can be an array of parallel lines and spaces between the lines. FIG. 24 shows an example of such an interference pattern array layout 2400.

Returning to FIG. 22, the actor can determine the difference between the design layout from the interference pattern array layout at 2215. The determination of the difference between the design layout and the interference pattern array layout can include aligning trenches in the design layout with either lines or spaces in the interference pattern array layout and determining positions where irregularity in the design layout prevents complete overlap with the interference pattern array layout.

The determination can yield a remainder layout that indicates positions where the design layout does not completely overlap with the interference pattern array layout. The remainder layout can be in machine-readable form. The difference can be Boolean in that positions in the remainder layout can have only one of two possible states.

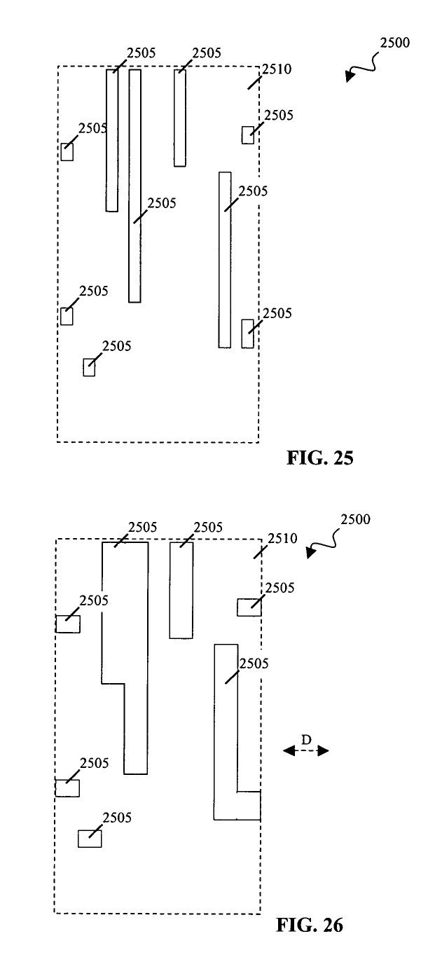

FIG. 25 shows an example remainder layout 2500. Remainder layout 2500 is a Boolean difference. In particular, remainder layout 2500 includes expanses of first positions 2505 with a “not overlapped” state and a contiguous expanse of second positions 2510 with an “overlapped” state.

Returning to FIG. 22, the actor can resize expanses of positions in the remainder layout at 2220. The resizing of the remainder layout can result in a changed machine-readable remainder layout. For example, when the interference pattern array is an array of parallel lines and spaces, the size of expanses with a present state can be increased in the direction perpendicular to the lines and spaces. FIG. 26 shows remainder layout 2500 after such an expansion in a direction D. Note that some expanses 2505 have merged.

Returning to FIG. 22, the actor can generate a print mask using a remainder layout at 2225. The print mask can be generated using the resized remainder layout to create arbitrarily shaped features for introducing irregularity into a repeating array, such as an interference pattern array. The generation of the print mask can include generating a machine-readable description of layout of the print mask. The generation of the print mask can also include tangibly embodying the print mask in a mask substrate.

Composite patterning can prove advantageous. For example, a single layout piece can be patterned with features using a higher resolution system or technique and the impact of those features can be modified or even eliminated using a lower resolution system or technique. For example, older generation, typically lower resolution, equipment can be used to modify the impact of higher resolution features, providing increased lifespans to the older equipment. Pattern density can be increased and processing cost decreased by devoting higher resolution systems to the production of higher resolution features while using less expensive, lower resolution systems for the modification of the continuity of those higher resolution features. For example, high resolution but relatively inexpensive interferometric systems can be combined with relatively inexpensive low resolution systems to produce high quality, high resolution patterns without large capital investments. Since the arrangement of patterns produced using interferometric systems can be changed using lower resolution systems, the applicability of interferometric systems can be increased. In particular, interferometric systems can be used to form arbitrary arrangements of features that are not constrained by the geometries and arrangements of interference patterns.

A number of implementations have been described. Nevertheless, it will be understood that various modifications may be made. For example, both positive and negative resists can be used. Lithographic techniques that use different wavelengths can be used to process the same substrate. Substrates other than semiconductor wafers can be patterned. Accordingly, other implementations are within the scope of the following claims.

1. A method comprising:
patterning a substrate with a substantially arbitrary arrangement of features by introducing irregularity into an array of repeating lines and spaces between the lines.

2. The method of claim 1, wherein introducing irregularity comprises forming an arbitrary figure above the array.

3. The method of claim 2, wherein patterning the substrate further comprises etching a substrate through portions of the array not covered by the arbitrary figure.

4. The method of claim 1, wherein introducing irregularity comprises reducing the continuity of at least a portion of the array, the array formed using an interference lithography system.

5. The method of claim 4, wherein reducing the continuity of the portion of the array comprises cutting spaces in the array.

6. The method of claim 1, wherein introducing irregularity comprises reducing the continuity of the portion of the array resulting from a projection lithography patterning.

7. The method of claim 1, wherein patterning the substrate further comprises etching the substrate using the substantially arbitrary arrangement to direct the etching.

8. The method of claim 1, wherein patterning the substrate further comprises patterning the substrate with the substantially arbitrary arrangement having a pitch yielding a k₁ factor smaller than or equal to 0.4.

9. A device, comprising:
a substantially arbitrary arrangement of trenches, the trenches defined with a definition characteristic of interference lithography.

10. The device of claim 9, wherein the substantially arbitrary arrangement of trenches comprises trenches including discontinuities at varying positions along the trenches.

11. The device of claim 9, wherein the substantially arbitrary arrangement of trenches comprises features printed with a pitch yielding a k₁ factor smaller than or equal to 0.5.

12. The device of claim 11, wherein the substantially arbitrary arrangement of trenches comprises trenches with a pitch yielding a k₁ factor approaching 0.25 for a single patterning step.

13. The device of claim 9, wherein the substantially arbitrary arrangement of trenches comprises trenches free from defects arising due to one or more of lens imperfections and mask imperfections.

14. The device of claim 9, wherein the substantially arbitrary arrangement of trenches comprises trenches free from defects arising due to backscatter of electrons.

15. The device of claim 9, wherein the substantially arbitrary arrangement of trenches comprises a portion of a microelectronic device.

16. A method comprising:
interfering electromagnetic radiation to illuminate a substrate with an interference pattern, the interference pattern imparting the substrate with repeating lines and spaces; and
introducing irregularity into the interference pattern to impart an arbitrary feature arrangement to the substrate.

17. The method of claim 16, wherein introducing irregularity comprises ending continuity of a trench at an arbitrary position along the trench.

18. The method of claim 16, wherein introducing irregularity comprises forming an arbitrary figure above some portion of the repeating lines and spaces.

19. The method of claim 16, wherein introducing irregularity comprises forming an arbitrary figure in some portion of the repeating lines and spaces.

20. The method of claim 17, further comprises patterning the substrate using the arbitrary figure to define the arbitrary feature arrangement.

21. The method of claim 16, wherein interfering electromagnetic radiation comprises imparting, to the substrate, first features having a pitch yielding a k₁ factor approaching 0.25 in a single patterning step.

22. A method comprising:
patterning a substrate using a first lithographic technique, the patterning providing lines and spaces with a first pitch yielding a first k₁ factor smaller than or equal to 0.5; and
eliminating the impact of at least some of one or more portions of the lines and spaces on the substrate using a second lithographic technique providing second features with a second pitch, the second pitch two or more times larger that the first pitch.

23. The method of claim 22, wherein patterning the substrate using the first lithographic technique comprises providing first lines and spaces with the first pitch yielding the first k₁ factor approaching 0.25 for a single patterning step.

24. The method of claim 22, wherein patterning the substrate using the first lithographic technique comprises patterning the substrate using interference lithography.

25. The method of claim 22, wherein eliminating the impact comprises patterning using a binary mask.

26. The method of claim 22, wherein eliminating the impact comprises using the second lithographic technique providing second features with the second pitch yielding the second k₁ factor greater than 0.5.

27. The method of claim 22, wherein eliminating the impact comprises printing an arbitrary figure above some of the spaces.

28. The method of claim 27, wherein eliminating the impact comprises etching a portion of the substrate not covered by the arbitrary figure.

29. The method of claim 27, wherein eliminating the impact comprises ending continuity of at least one or more portions of the lines and spaces.

30. An apparatus comprising:
an interference exposure module to produce a first exposure resulting in an array of repeating features in a photosensitive media; and
a second patterning module to reduce regularity of the features in the array.

31. The apparatus of claim 30, further comprising an alignment sensor to align a second exposure pattern produced by the second patterning module with the array.

32. The apparatus of claim 30, further comprising a common control system to regulate the interference exposure module and the second patterning module.

33. The apparatus of claim 30, further comprising a common wafer stage to present a wafer to the interference exposure module and to the second patterning module.

34. The apparatus of claim 30, wherein:
the interference exposure module comprises an interference lithography module; and
the second patterning module comprises a projection optical lithography system, the projection optical lithography system including
a mask to reduce regularity in the array created by the interference exposure module,
projection optics, and
a wafer stage.

35. A method comprising:
receiving a design layout of a layout piece;
receiving an interference pattern array layout;
determining a difference between the design layout and the interference pattern array layout; and
generating a print mask using the determined difference.

36. The method of claim 28, wherein generating the print mask comprises resizing a remainder array reflecting the difference between the design layout and the interference pattern array layout.
